(19) United States
(12) Patent Application Publication
(10) Pub. No.: US 2025/0255041 A1
(43) Pub. Date: Aug. 7, 2025

(54) SEMICONDUCTOR STRUCTURE

(71) Applicant: EPISTAR CORPORATION, Hsinchu (TW)

(72) Inventor: Chang-Tai HSIAO, Hsinchu (TW)

(21) Appl. No.: 19/046,289

(22) Filed: Feb. 5, 2025

(30) Foreign Application Priority Data
Feb. 7, 2024 (TW) 113104962

(51) Int. Cl. H10H 20/819; H10H 29/14

(52) U.S. Cl. CPC H10H 20/819; H10H 29/14

(57) ABSTRACT

A semiconductor structure includes a substrate and a semiconductor stack. The substrate has a first surface and a second surface, the first surface has a first protruding unit and a second protruding unit which are arranged in a horizontal direction, and the second surface has a third protruding unit and a fourth protruding unit which are arranged in the horizontal direction. In a vertical direction perpendicular to the horizontal direction, the first protruding unit overlaps the third protruding unit, and the second protruding unit overlaps the fourth protruding unit. The semiconductor stack connects to the first surface. If the second surface is irradiated by a light beam which is parallel to the vertical direction, the light beam is capable of substantially forming a uniform energy distribution on the first surface.

### CROSS-REFERENCE TO RELATED APPLICATIONS

This application claims priority to, and the benefit of, Taiwan Patent Application Number 113104962 filed on Feb. 7, 2024, the entirety of which is hereby incorporated by reference.

### TECHNICAL FIELD

The present disclosure relates to a semiconductor structure, and, in particular, to a semiconductor structure including a substrate and a semiconductor stack.

### DESCRIPTION OF BACKGROUND ART

The light-emitting diode (LED) is a semiconductor device which has many advantages, such as small size, low power consumption, high brightness, long operating life, and fast reaction speed. Therefore, it has been regarded as an mainstream technology for next-generation lighting and display devices.

After the LED is formed on a growth substrate, the growth substrate is usually separated from the LED to reduce the size of the device. Laser lift-off (LLO) is a lift-off method that uses a laser with a specific wavelength to irradiate the interface between the growth substrate and the LED in a direction perpendicular to the surface of the growth substrate. The material at the interface is heated under laser irradiation, causing the bonds to break and the material to vaporize, thus achieving the purpose of separation. When a patterned sapphire substrate (PSS) is used as the growth substrate, the uneven surface morphology of the growth substrate causes uneven energy distribution of the laser on the interface. The interface with insufficient energy cannot be vaporized and separated, and the interface with excessive energy will damage the semiconductor structure of the LED.

### SUMMARY

The present disclosure provides a semiconductor structure and a method and system processing thereof, which can slove the above-mentioned problems.

In one embodiment, a method of processing a semiconductor structure includes: providing the semiconductor structure which comprises a substrate and a semiconductor stack, wherein the substrate has a first surface connected to the semiconductor stack and extending along a horizontal direction, the first surface has a first protruding unit and a second protruding unit which are arranged adjacent to each other, the first protruding unit has a top, and a first inclined surface and a second inclined surface which are located on two sides of the top; and providing a light beam to pass through the substrate for irradiating the first surface to separate the substrate and the semiconductor stack, wherein the light beam includes a first sub-beam arranged for perpendicularly exiting the first inclined surface.

A semiconductor structure according to an embodiment of the present disclosure includes a substrate and a semiconductor stack. The substrate has a first surface and a second surface which are parallel to the horizontal direction and arranged in a position opposite to each other in the vertical direction. The first surface has a first protruding unit and a second protruding unit which are arranged adjacent to each other. The semiconductor stack is connected to the first surface. The second surface has a third protruding unit and a fourth protruding unit which are arranged adjacent to each other. The first protruding unit and the third protruding unit are overlapped in the vertical direction, and the second protruding unit and the fourth protruding unit are overlapped in the vertical direction. If the second surface is irradiated by a light beam which is parallel to the vertical direction, the light beam is capable of substantially forming a uniform energy distribution on the first surface.

A processing system according to the embodiment of the present disclosure includes a laser source, a carrier and an optical module. A laser source is configured to provide a light beam. The carrier is configured to support a semiconductor structure. The semiconductor structure includes a substrate and a semiconductor stack. The substrate has a first surface connected to the semiconductor stack. The first surface has a plurality of protruding units arranged in an array. The optical module includes a lens array and arranges to guide the light beam to pass through the substrate, wherein the light beam is arranged for forming a substantially uniform energy distribution on the first surface.

### BRIEF DESCRIPTION OF THE DRAWINGS

The embodiments of the present disclosure can be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1 illustrates a cross-sectional view of a semiconductor structure in accordance with one embodiment of the present disclosure.

FIG. 2 is a schematic diagram of the energy distribution when the light beam irradiates the substrate.

FIG. 3 illustrates a cross-sectional view of a semiconductor structure in accordance with one embodiment of the present disclosure.

FIGS. 4 and 5 illustrate a cross-sectional view of a semiconductor structure in accordance with multi embodiments of the present disclosure.

FIG. 6 is a schematic diagram of a semiconductor structure processing system in accordance with one embodiment of the present disclosure.

### DETAILED DESCRIPTION OF THE APPLICATION

The present disclosure provides many different embodiments that can be used to implement different features of the disclosure. To simplify illustration, examples of specific elements and arrangements are also described in this disclosure. These examples are provided for illustrative purposes only and are not intended to be limiting. The disclosure may repeat symbols and/or characters of components in different embodiments or examples. This repetition is for simplicity and clarity, rather than to represent the relationship between the different embodiments and/or examples discussed.

In addition, for convenience of description, spatially relative terms such as “below”, “under”, “lower”, “above,” “upper”, “on”, “top,” “bottom” and the like may be used herein to describe relationship of one component or feature to another (or other) component or feature as shown in the figures. Spatially relative terms are intended to comprise different orientations of the component in use or operation in addition to the orientations shown in the figures. The component may be otherwise oriented (rotated 90 degrees or in other orientations) and the spatially relative descriptions used herein may be interpreted accordingly.

Although this disclosure uses terms such as first, second, or third to describe devices, elements, components, regions, layers, and/or sections, it should be understood that these devices, elements, components, regions, layers, and/or or sections shall not be limited by these terms. These terms are only used to distinguish one device, element, component, region, layer and/or section from another device, element, component, region, layer and/or section and do not imply or represent any ordinal. These terms do not imply the order of arrangement of one component relative to another component, or the order of manufacturing processes. Thus, a first device, element, component, region, layer and/or section discussed below could be termed a second device, element, component, region, layer and/or section without departing from the scope of embodiments of the disclosure.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. It should be noted that the stated value of the present disclosure is an approximate value. That is when there is no specific description of the terms “about,” “approximately” and “substantially”, the stated value includes the meaning of “about,” “approximately” or “substantially”. If the first direction is perpendicular or “substantially” perpendicular to the second direction, the angle between the first direction and the second direction may be between 80 and 100 degrees; If the first direction is parallel or “substantially” parallel to the second direction, the angle between the first direction and the second direction may be between 0 degrees and 10 degrees.

Although the present disclosure is described below through specific embodiments, the inventive principles of the present disclosure may also be applied to other embodiments. Additionally, certain details may be omitted so as not to obscure the spirit of the disclosure.

The present disclosure relates to a semiconductor structure, and a method and a system for processing the semiconductor structure. The semiconductor structure and the method of processing thereof according to the embodiment of the present disclosure provide a uniform energy distribution on the dissociation interface, thereby improving the dissociation yield.

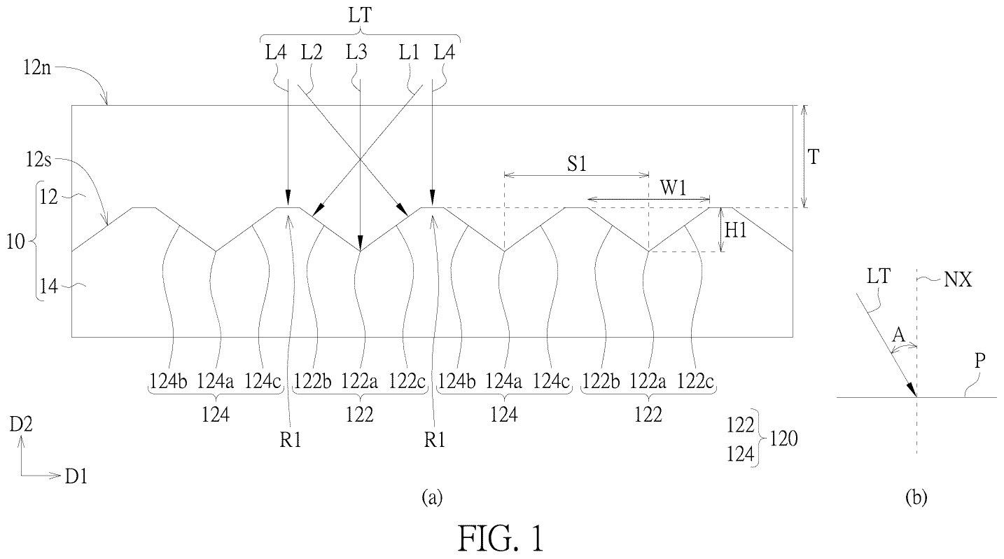

Please refer to FIG. 1. FIG. 1(a) is a cross-sectional view of a semiconductor structure 10 according to an embodiment of the present disclosure, FIG. 1(b) is a schematic diagram of an incident angle A of a light beam LT. The method includes providing a semiconductor structure 10, wherein the semiconductor structure 10 includes a substrate 12 and a semiconductor stack 14. For clarity, a direction for measuring the thickness T of the substrate 12 is defined as a vertical direction D2, and an extending direction of the surface of the substrate 12 is defined as a horizontal direction D1. The substrate 12 has a first surface 12s and a second surface 12n extending along the horizontal direction D1 and facing each other in the vertical direction D2. The first surface 12s has an uneven surface morphology and is connected to the semiconductor stack 14. In one embodiment, the substrate 12 has a sidewall connecting the first surface 12s and the second surface 12n. The sidewall extends along the vertical direction D2 and is substantially perpendicular to the horizontal direction D1. The method further includes providing a light beam LT. The light beam LT passes through the substrate 12 and irradiates the first surface 12s. The light beam LT irradiates an interface between the substrate 12 and the semiconductor stack 14 in a direction substantially perpendicular to the first surface 12s with a substantially uniform energy distribution. In one embodiment, the energy of the light beam LT can change the state of the material in the interface between the semiconductor stack 14 and the first surface 12s, such as bond breaking, vaporizing, melting, etc., thereby separating the substrate 12 and the semiconductor stack 14.

The first surface 12s of the substrate 12 has a plurality of protruding units 120 arranged in an array. The plurality of protruding units 120 includes a plurality of first protruding units 122 and a plurality of second protruding units 124 that are arranged alternately. A depression R1 is located between the protruding units 122 and 124. The first protruding unit 122 and the second protruding unit 124 both have a tapered cross section. The tapered cross section of the first protruding unit 122 has a top 122a, a first inclined surface 122b and a second inclined surface 122c are located at two sides of the top 122a. The tapered cross section of the second protruding unit 124 has a top 124a, a first inclined surface 124b and a second inclined surface 124c are located at two sides of the top 124a. In one embodiment, a width W1 of the first protruding unit 122 and a width W1 of the second protruding unit 124 in the horizontal direction D1 are about 2.8 um, and a height H1 of the first protruding unit 122 and a height H1 of the second protruding unit 124 in the vertical direction D2 are about 1.75 um. A distance S1 between two adjacent protruding units 122 and 124 in the horizontal direction D1 is about 3.0 um, wherein the distance S1 can be the horizontal distance between the two tops 122a and 124a, as shown in FIG. 1(a). In one embodiment, the widths W1 of the protruding units 122 and 124 are about 2.6 um, the heights H1 are about 1.6 um, and the distance S1 between two adjacent protruding units 122 and 124 is about 3 um. In one embodiment, the angles between the first inclined surfaces 122b, 124b and the horizontal direction D1 or between the second inclined surfaces 122c, 124c and the horizontal direction D1 are between 66 degrees and 45 degrees. In one embodiment, the first inclined surfaces 122b, 124b and the second inclined surfaces 122c, 124c have variable angles with the horizontal direction D1, and the inclined surfaces 122b, 124b, 122c, 124c can be continuous curved surfaces with a constant radius or curved surfaces with different curvature radii.

The light beam LT is emitted to the first surface 12s along a direction from the substrate 12 toward the semiconductor stack 14. The semiconductor stack 14 connected to the first surface 12s absorbs the energy from the light beam to increase its temperature. When the temperature rises to the temperature of the dissociation reaction of the semiconductor stack 14, the surface of the semiconductor stack 14 connected to the first surface 12s starts to decompose and separate from the first surface 12s. For example, when the surface material of the semiconductor stack 14 is gallium nitride, the surface material starts to decompose into gaseous nitrogen and liquid gallium. It should be noted that the light beam LT of the present disclosure includes a plurality of sub-beams, and the incident directions of the plurality of sub-beams correspond to the shapes of the protruding units 120 of the first surface 12s. For example, the light beam LT includes a first sub-beam L1 exiting the first inclined surface 122b, a second sub-beam L2 exiting the second inclined surface 122c, a third sub-beam L3 exiting the top 122a, and a fourth sub-beam L4 exiting the depression R1. In one embodiment, the first sub-beam L1 and the second sub-beam L2 intersect with each other in the substrate 12.

As shown in FIG. 1(b), an incident angle A of the light beam LT is defined as the angle between the light beam LT and the normal line NX of the cutting plane P at the incident point. In one embodiment, the incident angles A of the first sub-beam L1 and the second sub-beam L2 are approximately 0degree. That is, the first sub-beam L1 exits the first inclined surface 122b along a direction substantially perpendicular to the first inclined surface 122b (normal direction), and the second sub-beam L2 exits the second inclined surface 122c along a direction substantially perpendicular to the second inclined surface 122c (normal direction). The third sub-beam L3 and the fourth sub-beam L4 exit the top 122a and the depression R1 respectively along a direction substantially perpendicular to the horizontal direction D1. In one embodiment, the incident angles A of the sub-beams L1, L2, L3, L4 are less than 10 degrees.

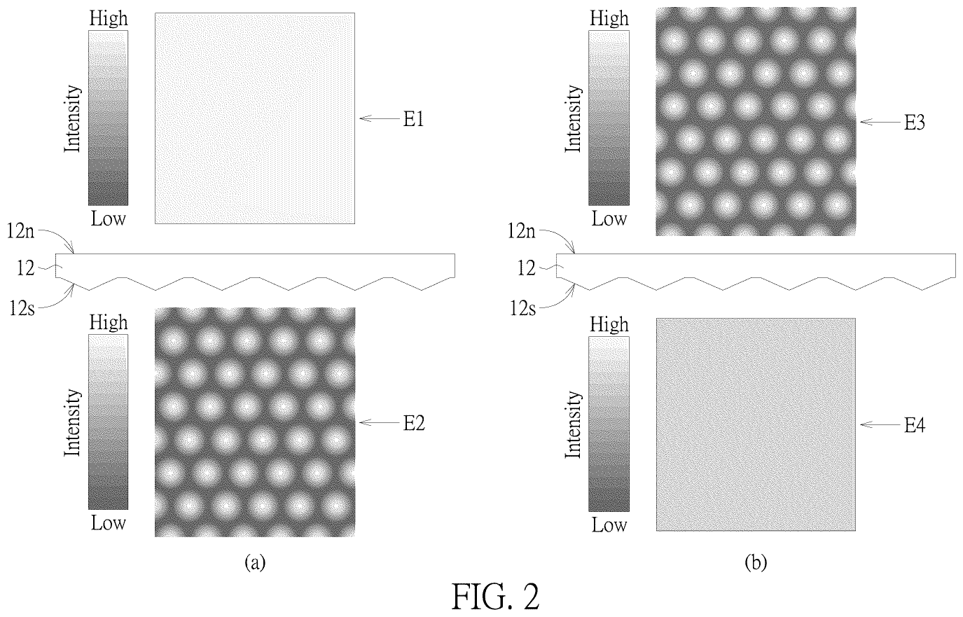

FIG. 2(a) is a diagram showing energy distributions on opposite sides of a substrate 12 when the substrate 12 is irradiated by a light beam using a conventional laser lift-off method, FIG. 2(b) is a diagram showing energy distributions on opposite sides of the substrate 12 when the substrate 12 is irradiated by a light beam in one embodiment of the present disclosure. The substrate 12 includes a first surface 12s and a second surface 12n opposite to the first surface 12s. The light beam LT irradiates the second surface 12n and passes through the substrate 12 to reach the first surface 12s. The energy distribution states E1 to E4 refer to energy distribution that appear or are measured on the first surface 12s and the second surface 12n when the light beam irradiates the substrate 12. The energy distribution states E1 and E4 have approximately uniform energy distributions. The energy distribution states E2 and E3 have multiple regularly arranged circles, wherein the closer to the center of the circle, the higher the energy intensity. The area between two adjacent circles presents a lower energy intensity. In the conventional laser lift-off method, a light beam with a uniform energy distribution state E1 is usually used to irradiate the second surface 12n. When the light beam passes through the substrate 12 and reaches the first surface 12s, the light beam is arranged for forming an uneven energy distribution state E2 on the first surface 12s. In the energy distribution state E2, the highest energy intensity appears at the top of the protruding unit, which is the central area of the circle in the figure. In one embodiment of the present disclosure, the light beam including a plurality of sub-beams is irradiated onto the second surface 12n in different directions, so that the sub-beams are forming an uneven energy distribution state E3 on the second surface 12n. When the light beam passes through the substrate 12 and reaches the first surface 12s, the light beam is forming a non-Gaussian energy distribution, such as a uniform energy distribution state E4, on the first surface 12s, that is, different parts of the first surface 12s (such as the inclined surface of the protruding unit 120, the top of the protruding unit 120, and the depression R1 between the protruding units 120) have almost the same energy intensity. The almost the same or approximately uniform energy distribution means that the difference between the highest energy intensity and the lowest energy intensity is less than 20% of the highest energy intensity. In one embodiment, the highest energy intensity in the energy distribution state E3 (such as the central area of the circle in the figure) is located at the thinnest part of the substrate 12, such as the position of the second surface 12n above the recess R1 in FIG. 1(a).

In one embodiment, the substrate 12 is a growth substrate for forming the semiconductor stack 14, and the material of the substrate 12 includes silicon (Si), germanium (Ge), lithium aluminate (LiAlO₂), zinc oxide (ZnO), silicon carbide (SiC), aluminum oxide (AlO), sapphire, gallium nitride (GaN), aluminum nitride (AlN), gallium arsenide (GaAs), or indium phosphide (InP). In one embodiment, the substrate 12 is a patterned sapphire substrate (PSS) having a patterned surface, and the patterned surface is a first surface 12s and includes a plurality of protruding units 120. The wavelength of the light beam LT is related to the material of the substrate 12, so that when the light beam LT passes through the substrate 12, the absorption rate of the light beam LT by the substrate 12 is less than 30%. In one embodiment, when the laser beam LT with a wavelength of 193 nm, 248 nm or 355 nm is used to irradiate the patterned sapphire substrate 12, the absorption rate of the laser beam LT by the substrate 12 is less than 30%.

The semiconductor stack 14 includes multiple layers of semiconductor, wherein each layer includes a III-V semiconductor material, such as a III-nitride semiconductor layer, a III-phosphide semiconductor layer, a III-arsenide semiconductor layer, or a III-phosphoarsenide semiconductor layer. In one embodiment, the semiconductor stack 14 includes a p-doped GaN layer, an undoped GaN layer, and an n-doped GaN layer. The semiconductor stack 14 is formed by metal-organic chemical vapor deposition (MOCVD), hydride vapor phase epitaxy (HVPE), molecular beam epitaxy (MBE), physical vapor deposition (PVD), or liquid-phase epitaxy (LPE). For clarity, the multilayer structure of the semiconductor stack 14 is omitted in the figure. The semiconductor stack 14 can be processed into a semiconductor device, such as a LED chip or an integrated circuit chip.

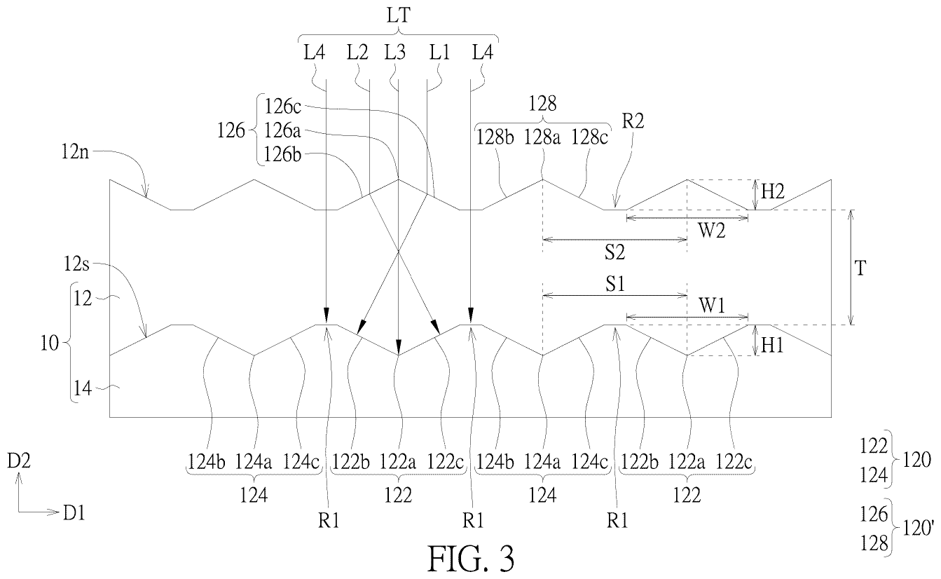

FIG. 3 is a cross-sectional view of a semiconductor structure 10 according to an embodiment of the present disclosure. One difference between FIG. 3 and FIG. 1 is the second surface 12n of the substrate 12 is also patterned with a plurality of protruding units 120′ arranged in an array at equal intervals, and the protruding units 120 of the first surface 12s are aligned with the protruding units 120′ of the second surface 12n in the vertical direction D2. When the light beam LT parallel to the vertical direction D2 irradiates to the second surface 12n of the substrate 12, a portion of the light beam LT entering the inclined surface of the protruding unit 120′ of the second surface 12n will be refracted and guided to the interface between the first surface 12s and the semiconductor stack 14 in a direction substantially perpendicular to the first surface 12s, wherein the light beam LT irradiating onto the interface has a substantially uniform energy distribution. In other words, when the light beam LT enters the substrate 12 as shown in FIG. 3 with the energy distribution state E1 as shown in FIG. 2, the energy distribution state E4 shown in FIG. 2(b) can be obtained on the first surface 12s.

As shown in FIG. 3, the protruding units 120′ of the second surface 12n includes a plurality of third protruding units 126 and a plurality of fourth protruding units 128 that are arranged alternately. The third protruding unit 126 includes a top 126a, a third inclined surface 126b and a fourth inclined surface 126c are located at two sides of the top 126a. The fourth protruding unit 128 includes a top 128a, a third inclined surface 128b and a fourth inclined surface 128c are located at two sides of the top 128a. In the vertical direction D2, the top 122a is opposite to the top 126a, the first inclined surface 122b is opposite to the third inclined surface 126b, the second inclined surface 122c is opposite to the fourth inclined surface 126c, the top 124a is opposite to the top 128a, the first inclined surface 124b is opposite to the third inclined surface 128b, and the second inclined surface 124c is opposite to the fourth inclined surface 128c. In addition, a depression R2 located between the third protruding unit 126 and the fourth protruding unit 128 is opposite to a depression R1 located between the first protruding unit 122 and the second protruding unit 124. A distance S2 between the third protruding unit 126 and the fourth protruding unit 128 in the horizontal direction D1 is substantially equal to a distance S1 between the first protruding unit 122 and the second protruding unit 124. In one embodiment, the protruding unit 120 and the protruding unit 120′ are mirror-symmetrical along the horizontal direction D1. In one embodiment, the protruding unit 120 and the protruding unit 120′ are mirror-symmetrical along the vertical direction D2, respectively.

As shown in FIG. 3, when the light beam LT irradiates the semiconductor structure 10 along the vertical direction D2, the first sub-beam L1 of the light beam LT passing through the substrate 12 from the fourth inclined surface 126c is refracted to the first inclined surface 122b, and the second sub-beam L2 passing through the substrate 12 from the third inclined surface 126b is refracted to the second inclined surface 122c. In one embodiment, the first sub-beam L1 enters the fourth inclined surface 126c by the fourth incident angle, and then exits the first inclined surface 122b by the first incident angle. The second sub-beam L2 enters the third inclined surface 126b by the third incident angle, and then exits the second inclined surface 122c by the second incident angle. The first incident angle is smaller than the fourth incident angle, and the second incident angle is smaller than the third incident angle. In one embodiment, the first sub-beam L1 and the second sub-beam L2 intersect in the substrate 12. The third sub-beam L3 of the light beam LT entering the substrate 12 from the top 126a is substantially exiting the top 122a along the vertical direction D2. The fourth sub-beam L4 of the light beam LT entering the substrate 12 from the depression R2 is substantially exiting the depression R1 along the vertical direction D2. In one embodiment, the protruding units 120′ on the second surface 12n of the substrate 12 can be used to refract the sub-beams to reduce the incident angle of the sub-beams to the first surface 12s. The incident angle can make the sub-beam irradiated onto the first surface 12s have a uniform energy intensity distribution, thereby solving the problem of incomplete peeling of or damage to the device structure.

The third protruding unit 126 and the fourth protruding unit 128 have a height H2 in the vertical direction D2 and a width W2 in the horizontal direction D1. The height H2, width W2 and cross-sectional contour of the third protruding unit 126 and the fourth protruding unit 128 can be adjusted according to adjust the thickness and material of the substrate 12, and can be the same or different as the height H1, width W1 and cross-sectional contour of the first protruding unit 122 and the second protruding unit 124. In one embodiment, the first protruding unit 122 and the third protruding unit 16 have the same widths W1 and W2, but the height H1 is greater than the height H2. In another embodiment, the height H1 is the same as the height H2, but the width W2 is greater than the width W1.

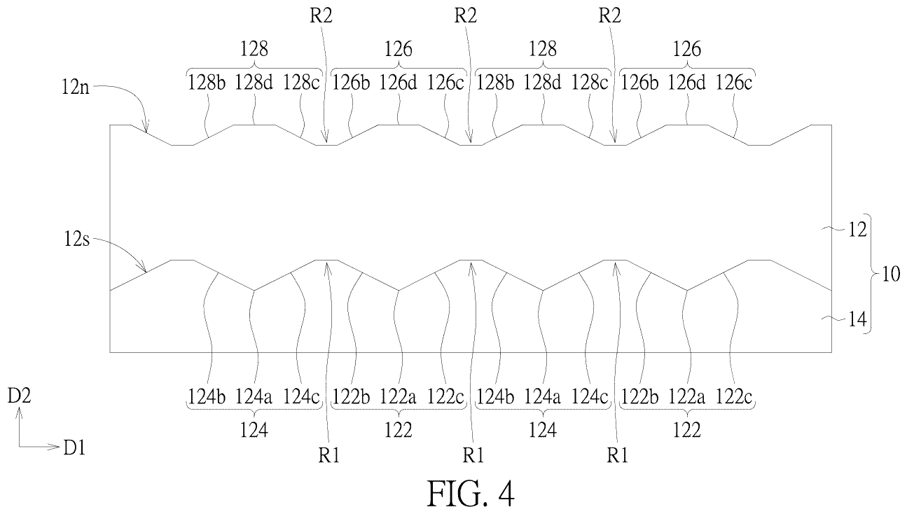

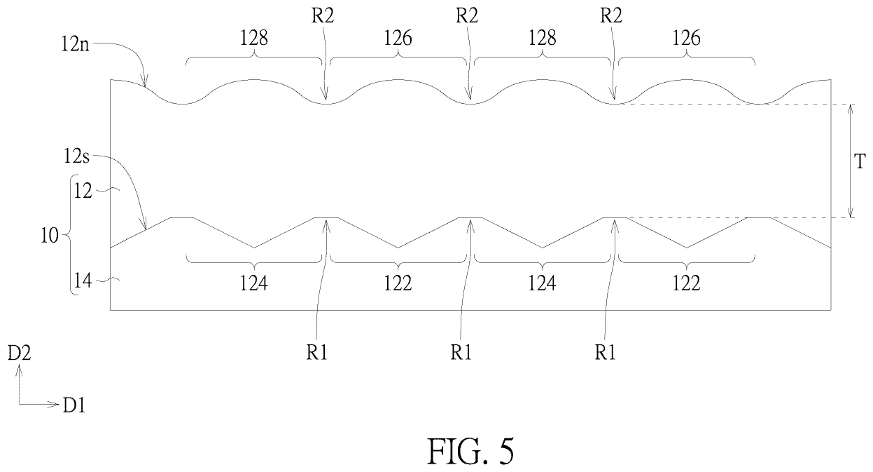

FIG. 4 and FIG. 5 are a cross-sectional view of a semiconductor structure 10. In one embodiment, the protruding unit 120′ has a contour so that when the sub-beams L1-L5 irradiate the interface between the substrate 12 and the semiconductor stack 14, the energy difference can be smaller than 20%. For example, the top 126d of the third protruding unit 126 and the top 128d of the fourth protruding unit 128 are flat surfaces parallel to the horizontal direction D1, as shown in FIG. 4. Alternatively, the third inclined surface of the third protruding unit 126 and the fourth inclined surface of the fourth protruding unit 128 are continuous curved surfaces with a constant radius or curved surfaces with different curvature radii, as shown in FIG. 5.

As shown in FIG. 5, in one embodiment, the third protruding unit 126 and the fourth protruding unit 128 together form a continuous curved surface. In a cross-sectional view, at least one protruding unit has a contour satisfying the relationship f=T/2≤R/(n−1). Wherein, f is the focal length of the light beam LT entering the substrate 12 via the second surface 12n, T is the thickness of the substrate 12 along the second direction D2 between the depressions R1 and R2, R is the radius of curvature of the protruding units 126 and 128, n is the refractive index of the light beam LT on the substrate 12 (for example, the refractive index n of the sapphire substrate is between 1.762 and 1.778). In other words, when the thickness T of the substrate 12 is larger, the curvature radius of the protruding units 126 and 128 is larger. When the material of the substrate 12 is changed so that its refractive index n becomes larger, the required curvature radius of the protruding units 126 and 128 becomes smaller.

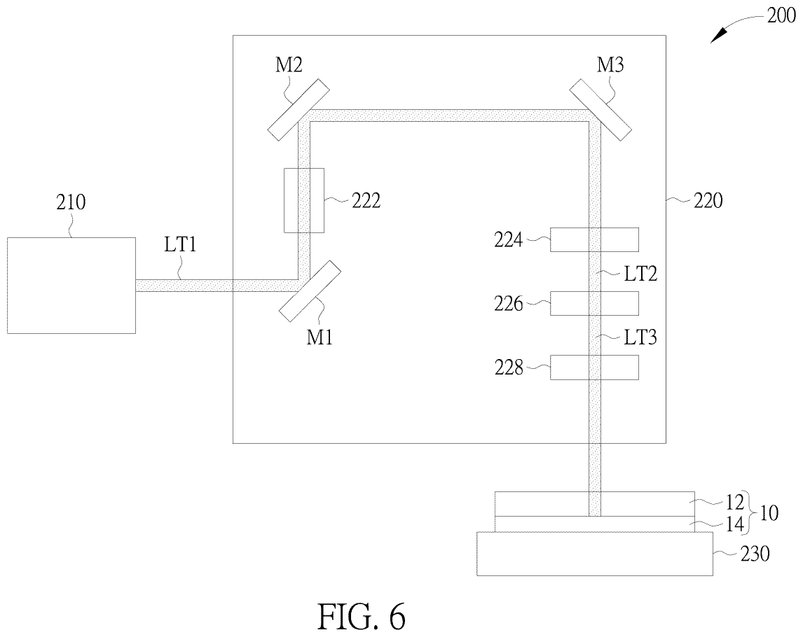

FIG. 6 is a system 200 for processing a semiconductor structure, wherein the system can process the semiconductor structure 10 as shown in FIGS. 1-5 to separate the semiconductor stack 14 from the first surface 12s of the substrate 12. As shown in FIG. 6, the system 200 includes a laser source 210, a carrier 230, and an optical module 220. The laser source 210 is used to provide a light beam LT1, which includes an excimer laser or a diode-pumped solid-state (DPSS) laser. The carrier 230 is used to support the semiconductor structure 10 and move the semiconductor structure 10 to adjust the position of the semiconductor structure 10 to receive the light beam. In one embodiment, the semiconductor structure 10 is placed on the carrier 230 with the substrate 12 facing the light beam LT3. The optical module 220 guides the light beam LT1 emitted by the laser source 210, includes a plurality of reflectors such as reflectors M1, M2, and M3, a light beam expander 222, a lens array 224, a light shield 226, and a reduction projection optical system 228. The reflectors M1, M2, and M3 are used to adjust the direction of the light beam LT1. The light beam expander 222 includes a plurality of convex lenses and concave lenses to expand the diameter of the light beam LT1. The lens array 224 includes a plurality of lens components arranged in an array perpendicular to the traveling direction of the light beam LT1. The lens array 224 is used to disperse the light beam LT1 into a plurality of light beams LT2. The plurality of light beams LT2 can have the same optical intensity and optical phase. In one embodiment, the lens components of the lens array 224 and the protruding units 120 of the substrate 12 have identical or similar arrangement. For example, the lens components of the lens array 224 are arranged in a closest packed arrangement, wherein the closest packed arrangement means that each lens component is arranged adjacent to six lens components. The light shield 226 has a plurality of holes or slits for shielding the outer portion of the light beam LT2 with weaker energy so as to convert it into a plurality of light beams LT3 for emission. The reduction projection optical system 228 is used to reduce the size of the light beam LT3 or focus the light beam LT3 onto a processing surface of the semiconductor structure 10 such as the interface between the substrate 12 and the semiconductor stack 14 or the second surface 12n of the substrate 12. In one embodiment, the light shield 226 and the reduction projection optical system 228 can be adjusted to fine-tune the inclined angle and focal length of the light beam LT3 entering the substrate 12, thereby adjusting the energy distribution of the light beam irradiating the substrate 12. The light beam LT3 includes the light beam LT in FIGS. 1 and 3, and includes the sub-beams L1-L5 in FIGS. 1 and 3, wherein the sub-beams L1-L5 can be irradiated to the substrate 12 at the same time or at different times.

In summary, the semiconductor structure, the processing method and the system provided in the present disclosure can obtain uniform energy distributions on the concave-convex dissociation surface of the semiconductor structure. Therefore, the problems of incomplete peeling and damage to the device structure during laser peeling off the PSS can be solved.

Although some embodiments of the present disclosure and their advantages have been described in detail, various changes, substitutions and alterations may be made herein without departing from the spirit and scope of the disclosure as defined by the appended claims.

What is claimed is:

1. A semiconductor structure, comprising:
a substrate, having a first surface and a second surface opposite to the first surface, wherein the first surface has a first protruding unit and a second protruding unit which are arranged in a horizontal direction, and the second surface has a third protruding unit and a fourth protruding unit which are arranged in the horizontal direction, in a vertical direction perpendicular to the horizontal direction, the first protruding unit overlaps the third protruding unit, and the second protruding unit overlaps the fourth protruding unit; and
a semiconductor stack, connected to the first surface;
wherein, if the second surface is irradiated by a light beam which is parallel to the vertical direction, the light beam is capable of substantially forming a uniform energy distribution on the first surface.

2. The semiconductor structure of claim 1, wherein the light beam is capable of substantially forming a uniform energy distribution on the second surface.

3. The semiconductor structure of claim 1, wherein the first protruding unit and the second protruding unit are separated by a first distance in the horizontal direction, and the third protruding unit and the fourth protruding unit are separated by a second distance in the horizontal direction, and the first distance is substantially equal to the second distance.

4. The semiconductor structure of claim 1, wherein the first protruding unit and the third protruding unit have tops overlapping with each other in the vertical direction.

5. The semiconductor structure of claim 1, wherein the substrate has a first depression and a second depression, the first depression is located between the first protruding unit and the second protruding unit, the second depression is located between the third protruding unit and the fourth protruding unit, and the first depression overlaps the second depression in the vertical direction.

6. The semiconductor structure of claim 1, wherein the first protruding unit has a first inclined surface and a second inclined surface, the second protruding unit has a third inclined surface and a fourth inclined surface, in the vertical direction, the first inclined surface overlaps the third inclined surface, and the second inclined surface overlaps the fourth inclined surface.

7. The semiconductor structure of claim 6, wherein the light beam comprises a first sub-beam and a second sub-beam, the first sub-beam enters the substrate via the fourth inclined surface and is refracted to the first inclined surface, and the second sub-beam enters the substrate via the third inclined surface and is refracted to the second inclined surface.

8. The semiconductor structure of claim 7, wherein the first sub-beam enters the fourth inclined surface by a fourth incident angle and exits the first inclined surface by a first incident angle, the second sub-beam enters the third inclined surface by a third incident angle and exits the second inclined surface by a second incident angle, the first incident angle is smaller than the fourth incident angle, and the second incident angle is smaller than the third incident angle.

9. The semiconductor structure of claim 8, wherein the first incident angle and the second incident angle are less than 10 degrees.

10. The semiconductor structure of claim 7, wherein the first sub-beam and the second sub-beam intersect with each other in the substrate.

11. The semiconductor structure of claim 1, wherein, in a cross-sectional view, the first protruding unit and the third protruding unit have different contours.

12. The semiconductor structure of claim 1, wherein the third protruding unit has a top with a flat surface parallel to the horizontal direction.

13. The semiconductor structure of claim 1, wherein, in the vertical direction, the first protruding unit has a first height, the third protruding unit has a second height, the first height is different from the second height.

14. The semiconductor structure of claim 13, wherein the first height is greater than the second height.

15. The semiconductor structure of claim 1, wherein, in the horizontal direction, the first protruding unit has a first width, the third protruding unit has a second width, the first width is different from the second width.

16. The semiconductor structure of claim 15, wherein the first width is smaller than the second width.
